(19) United States
(12) Patent Application Publication
(10) Pub. No.: US 2005/0272249 A1
(43) Pub. Date: Dec. 8, 2005

(54) Method and system for producing conductive patterns on a substrate

(75) Inventors: Andreas Karl, Tegernheim (DE); Andreas Muller-Hipper, Regensburg (DE); Frank Puschner, Kelheim (DE); Ewald Simmerlein-Erlbacher, Ottobrunn (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/137,698

(22) Filed: May 24, 2005

Related U.S. Application Data
(63) Continuation of application No. PCT/DE03/03436, filed on Oct. 16, 2003.

(30) Foreign Application Priority Data
Nov. 25, 2002 (DE) 102 54 927.3

(51) Int. Cl. H01L 21/4763

(52) U.S. Cl. 438/622

(57) ABSTRACT

A method of producing a conductive pattern on a substrate, including the steps of providing a surface of the substrate with a conductive layer, which is formed by providing the surface of the substrate at least partly with conductive particles, by directly using the adhesive power of the surface of the substrate, applying a passivation layer to the conductive layer, the passivation layer being formed as a negative image of the conductive pattern, and forming the conductive pattern in the regions not covered by the passivation layer.

### CROSS-REFERENCE TO RELATED APPLICATION

This application is a continuation of International Patent Application Serial No. PCT/DE2003/003436, filed Oct. 16, 2003, which published in German on Jun. 10, 2004 as WO 2004/049771, and is incorporated herein by reference in its entirety.

### FIELD OF THE INVENTION

The invention relates to a method of producing conductive patterns on a substrate.

### BACKGROUND OF THE INVENTION

The production of conductive patterns on a substrate is to be performed as inexpensively as possible. This is important in particular in the case of products which are produced in large numbers. An example of such products is that of printed circuit boards, in which an identical conductive pattern must be reproduced many times. This equally applies in the production of carrier tapes for chip card modules. The conductive pattern realized on such a carrier tape represents for example an antenna for contactless chip cards (RFID) or forms a conductor pattern which serves for bringing the semiconductor chip into electrical contact with the antenna or else the external contacts.

Production of such a conductive pattern is performed for example by means of plastic metallization laminates, for which firstly a metal foil—generally of copper—is applied to the full surface area of a nonconducting substrate (carrier film) The conductive pattern is created by photolithography or a printing technique and a subsequent etching operation. If a conductive pattern is desired on both sides of the substrate, a plastic metallization laminate which is provided with the metal foil on both sides of the nonconducting substrate is used. The patterning then takes place on both sides in the procedure described. Via holes for establishing electrical connection of the conductive patterns located on the opposite sides of the substrate are provided by a subsequent electroplating step.

An alternative variant for the production of a conductive pattern is to realize the desired layout by the printing of conductive pastes. Polymeric ink with conductive silver particles is often used as the conductive paste. In order to ensure adequate conductivity, a high proportion of conductive silver particles is required in the conductive paste, as a result of which this method causes high costs. Although the printing method makes it possible to produce substrates patterned on both sides in a simple way, the provision of via holes (establishing electrical connection between the conductive patterns situated on the opposite sides of the substrate) is not possible. A further processing step is necessary for this.

The two production methods described—patterning by means of an etching technique or printing with a conductive paste—cause high costs on account of the many necessary process steps and on account of the great loss of material. Via holes necessitate additional working steps. Not least, the environmental impact caused by the great loss of material is to be taken into account as a disadvantage.

A further, but rarely used, method of producing conductive patterns is that of punching out the conductive pattern from a metal foil and subsequently fixing it adhesively on the substrate. The high costs of this procedure are caused by the great loss of material involved in punching out from the metal foil. Furthermore, the direct provision of via holes is not possible.

Because of the same disadvantages, wire-wound structures are no longer used in the production of printed circuit boards or chip card modules.

### SUMMARY OF THE INVENTION

It is therefore an object of the present invention to provide a method of producing conductive patterns on a substrate which is simple and inexpensive.

According to the invention, it is envisaged firstly to cover a surface of the substrate at least partly with conductive particles, subsequently to apply a passivation layer to the layer of particles formed by the conductive particles, the passivation layer being formed as a negative image of the conductive pattern to be created, and finally to form the conductive pattern in the regions not covered by the passivation layer.

The provision of a layer of particles under a passivation layer makes it possible to form the conductive patterns by galvanic processes that can be easily controlled and are inexpensive. As is evident from the advantageous refinements described below, the invention is advantageously suitable for producing conductive patterns with a layout which frequently has to be changed. In particular, the method can therefore be used for producing small batches of patterned substrates.

### BRIEF DESCRIPTION OF THE DRAWINGS

The invention and its advantages are explained in more detail with the aid of an example and on the basis of the figures which follow, in which:

FIG. 1 shows a substrate after the application of conductive particles;

FIG. 2 shows the arrangement after the application of a passivation layer;

FIG. 3 shows the arrangement after the creation of a conductive pattern; and

FIG. 4 shows the arrangement after the creation of a conductive pattern which has been created by two production steps.

### DETAILED DESCRIPTION OF PREFERRED EMBODIMENTS OF THE INVENTION

In the figures which follow, the method of producing conductive patterns on a substrate 10 in various production steps is described.

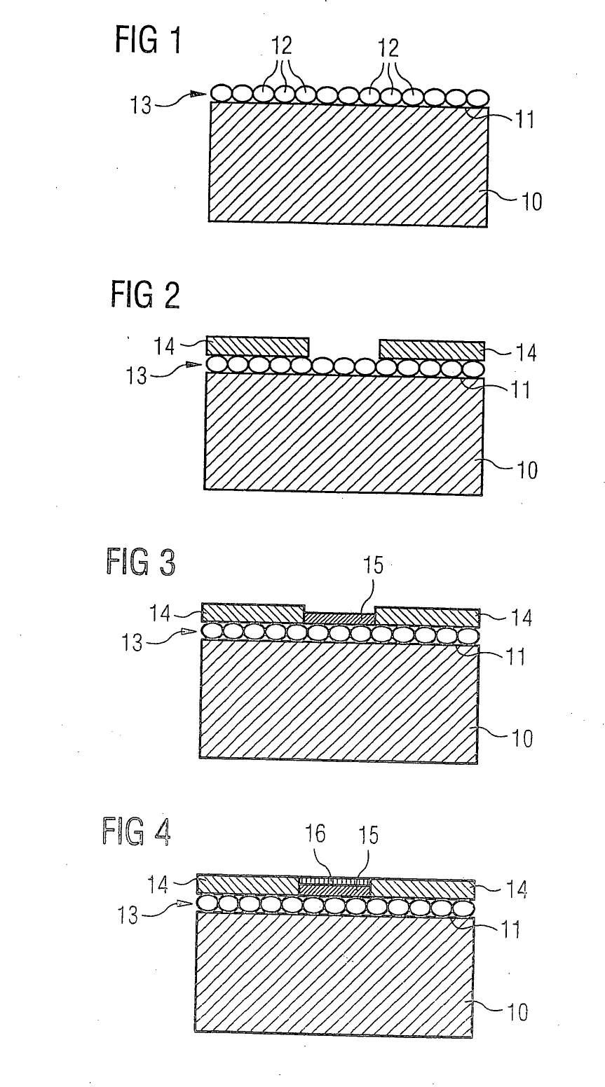

In FIG. 1, a layer of particles 13 has been applied to a surface 11 of the substrate 10. The layer of particles 13 comprises conductive particles 12. These consist of a metal, for example iron or copper, or of a polymer. The individual conductive particles are arranged alongside one another on the surface 11. There is no electrical connection between adjacent conductive particles 12. This can be ensured by the conductive particles 12 having a non-conducting surface. In this respect, it is not necessary to create this non-conducting surface by a special treatment of the conductive particles. The oxidation produced on the surface of any metal is already adequate to prevent an electrical contact. An electrical connection can also be prevented by the conductive particles, which have been applied to the surface 11 for example by means of blowing, spraying or printing them on, being spaced apart from one another. On the other hand, an electrical conductivity in the z direction (which in the present drawing sheet runs vertically from the bottom to the top) is harmless and even desired.

The substrate 10 may be any desired material. The use of plastic, glass, fabric or the like is possible. If the substrate 10 consists of a plastic, it is advantageous to apply the conductive particles directly after it has been produced in its final form. If the conductive particles are applied directly after the substrate is discharged from a calender, it is possible to dispense with the use of an adhesive to establish adequate adherence of the conductive particles. If, on the other hand, a glass, a fabric, a stone or the like is used as the substrate, attachment of the conductive particles by means of a layer of adhesive is necessary.

Conductive particles of a polymer may be applied to the substrate instead of conductive particles of a metal. In this case, it must be ensured that electrical conductivity is prevented in the x and y directions (i.e., the axes lying parallel to the surface of the substrate). This can take place for example by adjacent particles being applied in such a way that they do not collide.

In the case of the present method, it is also immaterial what surface the substrate 10 has. In the present exemplary embodiment of FIG. 1, the substrate 10 is rectangular in cross section. On the other hand, the surface 11, or any surface that is to be provided with a conductive pattern, could have any desired curvature.

Once the surface 11 of the substrate 10 has been covered with the conductive particles 12 (completely or else only partly), a passivation layer 14 is subsequently applied to the layer of particles 13 formed by the conductive particles 12. The application of the passivation layer 14 in this case preferably takes place already in the patterned form, those regions which are later to represent the conductive pattern remaining uncovered by the passivation layer. In other words, this means that the passivation layer 14 represents a negative image of the later conductive pattern.

In the present FIG. 2, the passivation layer 14 has, by way of example, two regions. The forming of a conductive pattern is prevented at these locations. The conductive pattern, which for example represents a conductor track of any desired configuration, is consequently created in the region not covered by the passivation layer 14.

The application of the passivation layer preferably takes place by a printing method. In this respect, conventional laser or ink-jet printers may be used. The use of an offset printing machine is also conceivable. The particular advantage of applying the passivation layer by means of a printing method is that different layouts of conductive patterns can be created in a simple way without expenditure on apparatus. The layout created on a computer can be printed directly by the printer onto the substrates provided with the layer of particles. The use of a printing method additionally has the advantage that a better resolution is possible in comparison with known methods of producing conductive patterns. The fineness of the conductive pattern to be created is determined only by the resolution of the printer. The use of an offset, laser or ink-jet printing method is advantageous. The subsequent further treatment, which will be described in FIGS. 3 and 4, allows the desired layout to be created. It is possible to dispense with the use of a complicated photolithography method with a subsequent etching operation according to the prior art. The proposed method can therefore be used more flexibly than the methods known from the prior art, and in particular with less expense.

In a further variant, the application of the passivation layer firstly takes place by means of a photoresist over the full surface area of the layer of particles and subsequently a photographic masking is performed for the formation of the conductive pattern. Nevertheless, an etching operation is not necessary.

The cost-efficient production also results from the subsequently performed production step of forming the conductive patterns. In FIG. 3, the conductive pattern is provided by a direct reinforcement of the regions of the layer of particles 13 not covered by the passivation layer 14. In this exemplary embodiment, the conductive particles preferably consist of iron. Once the arrangement represented in FIG. 2 has been immersed in a copper bath, an ion exchange process takes place between the non-precious metal iron and the precious metal copper. As a result, the layer of copper provided with the reference numeral 15 grows on the conductive particles 12. Depending on how long the arrangement remains immersed in the copper bath, the thickness of the conductive pattern 15 can be controlled. In particular, it is possible to make it terminate in a plane with the passivation layer 14.

In one embodiement, the forming of the conducting pattern takes place by “activation” of the regions of the conductive particles not covered by the passivation layer. In FIG. 4, the conductive pattern 15 is firstly provided by activation of the regions of the layer of particles 13 not covered by the passivation layer 14. Here, the particles preferably consist of copper. The conductive pattern 15 is provided by activation in an immersion bath, which for example contains silver. As a result, silver becomes attached to the conductive particles. After the arrangement has stayed in the immersion bath for a short time, the conductive pattern is then formed. The activation may likewise be performed by performing an electroplating process. The regions of the layer of particles not covered by the passivation layer provide for rapid forming of the conductive pattern. The use of any currently known electroplating method is possible in this case.

The arrangement represented in FIG. 2 can also be subjected to a galvanic process. In order to improve the electrical conductivity of the pattern provided with the reference numeral 15, a galvanic and/or chemical reinforcement has subsequently been performed, whereby the layer 16 has been created. It is also possible in the case of this embodiment to make the conductive pattern created terminate flush with the surface of the passivation layer 14. In an advantageous development of the invention, a galvanic and/or chemical reinforcement of the conductive pattern formed by the activation takes place. By this process, the thickness of the conductive pattern can be increased, so that the height of the conductor pattern, formed for example as conductor tracks, can be adapted to the thickness of the passivation layer. In this way, a visually attractive surface can be created. In addition, the cross section of the conductive pattern is increased, so that the resistance can be influenced in a favorable way.

In anoter embodiment, the forming of the conductive pattern takes place by direct reinforcement of the regions of the conductive particles not covered by the passivation layer. In the case of this variant, the particles preferably consist of iron (Fe). The forming of the conductive pattern takes place by an ion exchange process. If the arrangement comprising the substrate, the layer of Fe particles and the patterned passivation layer is introduced into a copper bath, an ion exchange takes place on account of the combination of a precious metal with a non-precious metal, so that copper builds up on the conductive iron particles. Depending on how long the arrangement is left in the copper bath, the thickness of the conductive pattern can be influenced. Instead of Cu and Fe, any other combination of precious/non-precious metal which has an ion exchange process can also be used.

The method is used with preference for the production of conductor track patterns, of chip cards or of printed circuit boards; it can be used in principle for the production of any conductive pattern.

In FIGS. 1 to 4, the basic procedure of the method according to the invention is represented. As mentioned at the beginning, this method can be carried out on substrates 10 of any desired configuration. In the production of printed circuit boards or chip card modules—that is to say substrates 10 which are of a substantially flat form—the production of a conductive pattern on both sides is frequently required. In this case, the steps represented and described in FIGS. 1 and 2 are carried out one after the other on the two opposite surfaces of the substrate 10. Expressed another way, this means that the negative images to be produced on the opposite surfaces are produced one after the other in the form of respective passivation layers 14. On the other hand, the forming of the respective conductive patterns on the two opposite surfaces of the substrate takes place in a single step. It is particularly advantageous here that via holes which are possibly to be produced, that is to say electrical connections between the conductor patterns on the opposite surfaces of the substrate, are created automatically. A further production step for the creation of the via holes is therefore not necessary.

1. A method of producing a conductive pattern on a substrate, comprising the steps of:
providing a surface of the substrate with a conductive layer, which is formed by providing the surface of the substrate at least partly with conductive particles, by directly using the adhesive power of the surface of the substrate;
applying a passivation layer to the conductive layer, the passivation layer being formed as a negative image of the conductive pattern; and
forming the conductive pattern in the regions not covered by the passivation layer.

2. The method as claimed in claim 1, wherein the step of forming the conductive pattern comprises the step of activating the regions of the conductive layer not covered by the passivation layer.

3. The method as claimed in claim 2, wherein the conductive pattern is galvanically and/or chemically reinforced.

4. The method as claimed in claim 1, wherein the step of forming the conductive pattern comprises the step of directly reinforcing the regions of the conductive layer not covered by the passivation layer.

5. The method as claimed in claim 1, wherein the step of applying the passivation layer is accomplished by using a printing method.

6. The method as claimed in claim 1, wherein the step of applying the passivation layer comprises the steps of:
applying the passivation layer over the full surface area of the conductive layer; and
performing a photolithographic masking for the formation of the conductive pattern.

7. The method as claimed in claim 1, wherein the conductive particles have a non-conducting surface when they are applied to the substrate.

8. The method as claimed in claim 1, wherein the conductive layer applied to the substrate consists of a material selected from the group consisting of a metal, a metal alloy, or a polymer.

9. The method as claimed in claim 1, wherein the method is used for the production of conductor track patterns of chip cards or printed circuit boards.

10. A system for producing a conductive pattern on a substrate, comprising:
means for providing a surface of the substrate with a conductive layer, which is formed by providing the surface of the substrate at least partly with conductive particles, by directly using the adhesive power of the surface of the substrate;
means for applying a passivation layer to the conductive layer, the passivation layer being formed as a negative image of the conductive pattern; and
means for forming the conductive pattern in the regions not covered by the passivation layer.

11. The system as claimed in claim 10, wherein the means for forming the conductive pattern comprises a means for activating the regions of the conductive layer not covered by the passivation layer.

12. The system as claimed in claim 11, wherein the conductive pattern is galvanically and/or chemically reinforced.

13. The system as claimed in claim 10, wherein the means for forming the conductive pattern comprises a means for directly reinforcing the regions of the conductive layer not covered by the passivation layer.

14. The system as claimed in claim 10, wherein the means for applying the passivation layer includes a printing system.

15. The system as claimed in claim 10, wherein the means for applying the passivation layer comprises:
means for applying the passivation layer over the full surface area of the conductive layer; and means for performing a photolithographic masking for the formation of the conductive pattern.

16. The system as claimed in claim 10, wherein the conductive particles have a non-conducting surface when they are applied to the substrate.

17. The system as claimed in claim 10, wherein the conductive layer applied to the substrate consists of a material selected from the group consisting of a metal, a metal alloy, or a polymer.

18. The system as claimed in claim 10, wherein the system is used for the production of conductor track patterns of chip cards or printed circuit boards.
